(19) United States
(12) Patent Application Publication
(10) Pub. No.: US 2025/0122413 A1
(43) Pub. Date: Apr. 17, 2025

(54) Multifunctional Adhesion Promoter for Semiconductor Device Packages

(71) Applicant: Wolfspeed, Inc., Durham, NC (US)

(72) Inventors: Afshin Dadvand, Durham, NC (US); Devarajan Balaraman, Apex, NC (US); Kuldeep Saxena, Sewickley, PA (US)

(21) Appl. No.: 18/487,665

(22) Filed: Oct. 16, 2023

(51) Int. Cl. C09J 179/08; C09J 9/02; H01L 21/56; H01L 23/00; H01L 23/29; H01L 23/31; H01L 23/495

(52) U.S. Cl. CPC C09J 179/08; C09J 9/02; H01L 21/56; H01L 23/293; H01L 23/3135; H01L 23/49582; H01L 23/49586; H01L 24/29; H01L 24/32; H01L 23/49513; H01L 24/48; H01L 24/73; H01L 2224/29111; H01L 2224/29139; H01L 2224/29144; H01L 2224/29147; H01L 2224/29155; H01L 2224/29157; H01L 2224/32245; H01L 2224/48091; H01L 2224/48245; H01L 2224/73265; H01L 2924/01322; H01L 2924/0133; H01L 2924/10272; H01L 2924/1033; H01L 2924/12032; H01L 2924/12041; H01L 2924/13063; H01L 2924/13064; H01L 2924/13091

(57) ABSTRACT

Semiconductor device packages are provided. In one example, a semiconductor device package comprises a first structure having a first surface in the semiconductor device package, a second structure having a second surface in the semiconductor device package, and an adhesion promoting layer in contact with the first surface on a first side and the second surface on a second side. The adhesion promoting layer comprises a polyimide containing repeating units derived from a tetracarboxylic dianhydride and at least one diamine containing a functional group.

### FIELD

Example aspects of the present disclosure relate generally to semiconductor devices.

### BACKGROUND

Semiconductor devices, including power semiconductor devices based on wide bandgap materials, may be formed on a semiconductor wafer as part of a semiconductor fabrication process. The semiconductor wafer may be diced into many individual pieces, each containing one or more semiconductor devices. Each of these pieces may be a semiconductor die. The semiconductor die may need to be attached to other components as part of packaging of the semiconductor device. For instance, a semiconductor die, such as a wide bandgap semiconductor die, may need to be attached to a conductive lead frame for use in a discrete power semiconductor device package or a power module. Materials used to attach the semiconductor die to other components may need to provide a thermal, mechanical, and/or electrical connection of the semiconductor die to the other components.

### SUMMARY

Aspects and advantages of embodiments of the present disclosure will be set forth in part in the following description, or can be learned from the description, or can be learned through practice of the embodiments.

One example embodiment of the present disclosure is directed to a semiconductor device package. The semiconductor device package comprises a first structure having a first surface in the semiconductor device package, a second structure having a second surface in the semiconductor device package, and an adhesion promoting layer in contact with the first surface on a first side and the second surface on a second side. The adhesion promoting layer comprises a polyimide containing repeating units derived from a tetracarboxylic dianhydride and at least one diamine containing a functional group.

Another example embodiment of the present disclosure is directed to a semiconductor device package. The semiconductor device package comprises a semiconductor die comprising a wide bandgap semiconductor device, a submount, a die-attach material coupling the semiconductor die to the submount, an encapsulating material, and an adhesion promoting layer. The adhesion promoting layer comprises a polyimide containing repeating units derived from a tetracarboxylic dianhydride, a diamine benzoxazole, and a diamine benzimidazole.

Another example embodiment of the present disclosure is directed to a method of fabricating a semiconductor device package. The method comprises providing a polyimide precursor on a surface, curing the polyimide precursor to obtain a polyimide layer, and providing an electrically insulative material over the polyimide layer. The polyimide layer contains repeating units derived from a tetracarboxylic dianhydride and at least one diamine containing a functional group.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example semiconductor device package according to example embodiments of the present disclosure;

FIG. 2 depicts a cross-sectional view of an example first structure, second structure, and adhesion promoting layer according to example embodiments of the present disclosure;

FIG. 3 depicts a flow chart diagram of an example method according to example embodiments of the present disclosure;

FIG. 4 depicts a flow chart diagram of an example method according to example embodiments of the present disclosure; and

FIG. 5 depicts a flow chart diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to semiconductor device packages (e.g., discrete semiconductor device packages and power modules) for use in semiconductor applications and other electronic applications. In some embodiments, semiconductor device packages may include one or more semiconductor die having at least one semiconductor device. For instance, the semiconductor die may include, e.g., wide bandgap semiconductor devices, silicon carbide-based semiconductor devices (e.g., MOSFETs, Schottky diodes), Group III nitride-based semiconductor devices (e.g., high electron mobility transistor (HEMT) devices), etc.

In some semiconductor device packages, one or more semiconductor die may be attached to a submount (e.g., lead frame) using a die-attach material. More particularly, the die-attach material may be deposited on the submount, and the semiconductor die (or other component) may be placed on the die-attach material. The die-attach material may be subjected to bonding or a bonding process (e.g., sintering) to secure the semiconductor die (or other component) to the die-attach material. Various types of die-attach materials may be used to bond the one or more semiconductor die to the submount such as, for instance, metal sintering die-attach (e.g., silver (Ag) or copper (Cu)) and conductive adhesive die-attach.

After the die is attached to the submount, the die and at least a portion of the submount may be encapsulated by an insulating material (e.g., an epoxy molding compound (EMC)). However, the absence of chemical (e.g., covalent) bonding between EMC and different parts of the die and/or submount along with interfacial thermomechanical stress can pose reliability challenges such as interfacial delamination, performance and mechanical degradation, and failures. This is particularly problematic at high operational or testing temperature conditions (e.g., temperature cycle (TC) and high temperature reverse bias (HTRB) testing).

Delamination happens when the interfacial thermal or mechanical stress exceeds the intrinsic adhesion strength of the interface. The stress is usually caused and/or aggravated by mismatches in the coefficients of thermal expansion (CTE) of the EMC and different parts of a die, for instance, bare Cu or Ag- and/or Ni-plated lead frame, wire bonds (WB), metal interconnects, and passivation layers. Delamination may affect the electrical, mechanical, and thermal properties of the semiconductor device package.

Approaches to increasing the adhesion of EMCs with Cu lead frames have included, for example, chemical treatment of Cu lead frames to produce black CuO to increase surface roughness and provide mechanical interlocking sites for the EMC. Thiol-based self-assembly nanostructures (e.g., 4-aminothiophenol) have also been used as an interfacial adhesion promoter, mainly for Cu-EMC interfaces. The use of silane components (e.g., aminopropyltrimethoxysilane) has also been found to slightly improve the interfacial adhesion between semiconductor dies and EMCs.

While such approaches can slightly increase the peel strength of the EMC/lead frame or EMC/die interface, the approaches may fail to address the delamination issue on all parts of the package (e.g., polyimide, SiNx, Al metallization, solder, etc.) due to the lack of enough and/or efficient enough functional groups that can covalently bond to different surfaces having different surface chemistry and/or morphology. For example, there are many surfaces with differing morphology and/or chemistry in a discrete power package including, for example, Cu/CuO/Cu(OH)₂, Ni/NiO/Ni(OH)₂, Al/Al₂O₃/Al(OH)₃, H:SiOx, SiNx, SiC, Pb—Sn, Au, polyimides (PIs), and other organic layers. Addressing the delamination and associated failures of all of these surfaces separately would be extremely challenging. Further, thin layers of self-assembly nanostructures or thin-films of silanes as adhesion promoters may not be able to withstand the thermomechanical stresses posed at harsh operational or reliability test conditions such as TC, moisture sensitivity level (MSL) conditioning, HTRB, etc.

To address the problems explained above, the present inventors have discovered that a functionalized polyimide can be used as an adhesion promoter and stress buffer layer which can bond to an EMC and various other surfaces within a semiconductor device package to improve interfacial adhesion strength at multiple different interface types.

Accordingly, example aspects of the present disclosure are directed to a semiconductor device package comprising a first structure having a first surface, a second structure having a second surface, and an adhesion promoting layer in contact with the first surface on a first side and the second surface on a second side. The adhesion promoting layer comprises a polyimide containing repeating units derived from a tetracarboxylic dianhydride and at least one diamine containing a functional group. In some embodiments, the functional group is an azole (e.g., oxazole and/or imidazole). For example, in some embodiments, the polyimide comprises repeating units derived from a tetracarboxylic dianhydride, a diamine benzoxazole, and a diamine benzimidazole.

Different polyimide structures, as will be described below, can be selected to tune the surface/interface and overall thermo-mechanical properties of the adhesion promoting layer, while imidazole and oxazole moieties can efficiently bond/complex to transition metals, such as Cu, Ag, Ni, Pb, Pt, Au, and Ti. Metal-azole complexes also easily bond to EMCs, thus significantly increasing the interfacial adhesion strength at both surfaces, while also preventing or significantly mitigating any metal corrosion.

The incorporation of benzoxazole moieties in the polyimide can improve interchain interactions and thus enhance the mechanical properties of the adhesion promoting layer by improved interchain packing regularity. The incorporation of benzimidazole moieties in the polyimide can increase the glass temperature transition (Tg) values of the polymer by increasing interchain H-bonding. Different functional groups (e.g., glycidyl epoxide, aliphatic amine, or silane groups) can also further tune the polymer thermomechanical properties.

In some embodiments, the polyimide is prepared by combining a tetracarboxylic dianhydride with a diamine benzoxazole in a polar organic solvent (e.g., N,N-dimethylacetamide (DMAc) and/or N-methyl-2-pyrrolidone (NMP)) in a first vessel to form a first polyamic acid, combining a diamine benzimidazole with a tetracarboxylic dianhydride in a polar organic solvent in a second vessel to form a second polyamic acid, combining the first polyamic acid with the second polyamic acid to form a polyamic acid mixture, and heating the polyamic acid mixture to a temperature of about 50° C. to about 100° C. to form a polyimide precursor. A crosslinking agent (e.g., hexamethylenediamine) can be also added to the final solution.

In other embodiments, the polyimide precursor can be prepared by mixing a tetracarboxylic dianhydride, a diamine benzoxazole, a diamine benzimidazole, and a polar organic solvent to form a polyamic acid and heating the polyamic acid to a temperature of about 50° C. to about 100° C. to form the polyimide precursor.

The resulting polyimide precursor prepared by either of the methods described above can then be coated onto one or more structures within the semiconductor device package, degassed (e.g., at 50° C. to about 100° C.), and cured (e.g., at 150° C. to 350° C.) to complete the imidization process and form the polyimide. The coated structure can then be encapsulated by an EMC composition.

Advantageously, the polyimide adhesion promoter described herein can be used to bond to many different materials within the semiconductor device package, eliminating the need to find a separate material to promote adhesion between each different type of interface within the package.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

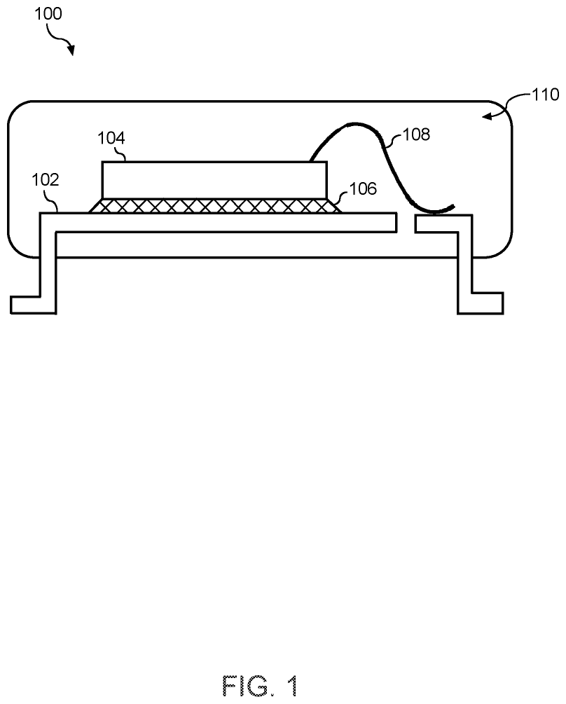

FIG. 1 depicts a cross-sectional view of at least a portion of a semiconductor device package 100 according to example embodiments of the present disclosure. The semiconductor device package 100 may include a submount 102 (e.g., a patterned conductive substrate). The submount 102 may be, for instance, a lead frame or other supporting structure of a wide bandgap power semiconductor device, such as a silicon carbide-based semiconductor power module or discrete package. The submount 102 may be, for instance, a copper submount 102 or may include other suitable conducting material(s).

The semiconductor device package 100 may include a semiconductor die 104, such as a wide bandgap semiconductor die 104. The semiconductor die 104 may include one or more devices, such as one or more of a wide variety of power devices available for different applications including, for example, power switching devices and/or power amplifiers. In some embodiments, the semiconductor die 104 may include one or more transistor devices, such as field effect transistors (FETs) devices, including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistor devices, etc. In some embodiments, the semiconductor die 104 may include one or more diodes (e.g., Schottky diodes, light emitting diodes, etc.).

In some embodiments, the semiconductor die 104 may be fabricated from wide bandgap semiconductor materials (e.g., having a band gap greater than 1.40 eV). For high power, high temperature, and/or high frequency applications, devices formed in wide bandgap semiconductor materials such as silicon carbide (e.g., 2.996 eV band gap for alpha silicon carbide at room temperature) and/or the Group III-nitrides (e.g., 3.36 eV band gap for gallium nitride at room temperature) may provide higher electric field breakdown strengths and higher electron saturation velocities. For instance, in some embodiments, the semiconductor die 104 may include a wide bandgap semiconductor device such as, e.g., a silicon carbide-based MOSFET or a silicon carbide-based Schottky diode. Additionally and/or alternatively, the semiconductor die 104 may include a wide bandgap semiconductor device such as, e.g., a Group III nitride-based high electron mobility transistor (HEMT).

Aspects of the present disclosure are discussed with reference to wide bandgap semiconductors for purposes of illustration and discussion. Those of ordinary skill in the art, using the disclosures provided herein, will understand that the adhesion promoting polyimide layer according to example embodiments of the present disclosure may be used with any semiconductor material or other material without deviating from the scope of the present disclosure.

The semiconductor die 104 may be attached to the submount 102 using, for instance, a sintering die-attach process and/or an electroless die-attach process. More specifically, the semiconductor die 104 may be attached to the submount 102 using a die-attach material 106. The die-attach material 106 may be placed on a surface of the submount 102, on a surface of the semiconductor die 104, or both a surface of the submount 102 and a surface of the semiconductor die 104. In some embodiments, the semiconductor device package 100 may include a die-attach material 106 between at least a portion of the semiconductor die 104 and at least a portion of the submount 102. The die-attach material 106 may include, for instance, solder, paste, sintered metal, etc. For instance, the die-attach material 106 may include a sintered metal such as, e.g., copper sintered metal and/or silver sintered metal.

In some embodiments, the semiconductor die 104 may also be connected to the conductive submount 102 using wire bonds 108. An encapsulating material 110 (e.g., epoxy molding compound) may fill the space around the semiconductor die 104 and the submount 102.

FIG. 1 is provided for purposes of illustration and discussion. Those of ordinary skill in the art, using the disclosures provided herein, will understand that aspects of the present disclosure may be used in a variety of devices and/or applications without deviating from the scope of the present disclosure.

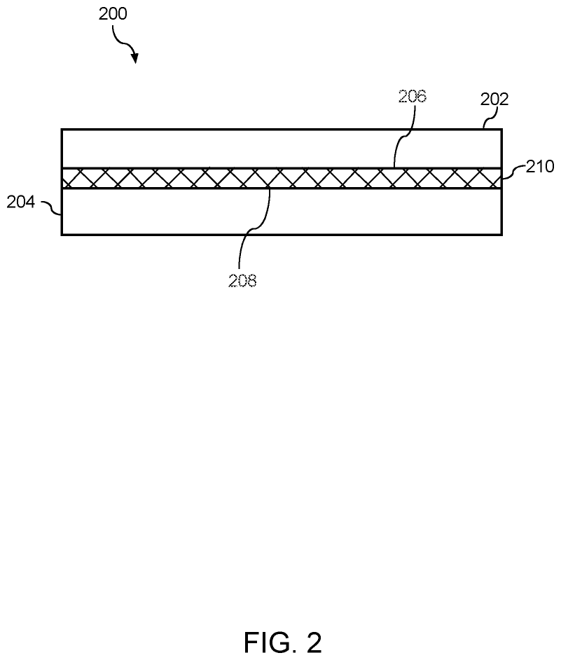

As explained above, the adhesion promoting layer described herein can be employed at one or more interfaces between the surfaces of any of the different structures within the semiconductor device package (e.g., between the encapsulating material 110 and the conductive submount 102, the semiconductor die 104, and/or the die-attach material 106). Such interfaces will be described in more detail below with reference to FIG. 2.

FIG. 2 depicts a cross-sectional view of at least a portion of a semiconductor device package 200 according to example embodiments of the present disclosure. The semiconductor device package 200 may include a first structure 202 and a second structure 204. The first structure 202 may have a first surface 206. The second structure 204 may have a second surface 208. An adhesion promoting layer 210 may be in contact with the first surface 206 on one side and in contact with the second surface 208 on a second side.

In some embodiments, the first structure 202 can be formed from an electrically insulating material. For example, the insulating material can contain an epoxy molding compound (EMC). EMCs typically contain an epoxy resin, a filler (e.g., silica), a hardener, and other additives. However, any EMC known in the art can be employed. As such, in some embodiments, the first surface 206 can comprise an epoxy resin.

In some embodiments, the second structure 204 can comprise an electrically conductive material. For example, the second structure 204 can be a submount (e.g., lead frame, clip structure, directed bonded copper (DBC) substrate, heat sink, or other submount)), a bond pad, a wire bond, a metal interconnect, or the like. In this regard, the second surface 208 of the second structure 204 may comprise one or more of a variety of different metal-containing materials. For example, the second surface 208 may comprise copper (Cu), nickel (Ni), aluminum (Al), tin (Sn), lead (Pb), gold (Au), silver (Ag), and/or any alloy (e.g., tin-lead), oxide, or hydroxide thereof.

In some embodiments, the second structure 204 can comprise a semiconductor material. For example, the second structure may comprise a semiconductor die. In this regard, the second surface 208 of the second structure 204 can comprise a semiconductor material, such as silicon (Si), silicon carbide (SiC), gallium arsenide (GaAs), LGO, zinc oxide (ZnO), LAO, indium phosphide (InP), and/or a Group III nitride (e.g. GaN, AlGaN and InGaN), and/or a dielectric material (e.g., passivation layer), such as silicon nitride (SiₓN_{y}), aluminum nitride (AlN), silicon dioxide (SiO₂), hydrogenated silicon oxides (H:SiOₓ), silicon oxynitrides (SiOₓN_{y}), magnesium oxide (MgO), scandium oxide (Sc₂O₃), aluminum oxide (Al₂O₃), and/or aluminum oxynitride (AlN)ₓ(Al₂O₃)₁₋ₓ. In some examples, the second surface 208 of the second structure 204 may also comprise an organic material, such as a polyimide.

In some embodiments, the first structure 202 is an encapsulating material (e.g., an epoxy molding compound) and the second structure 204 is a die-attach material. For example, the die-attach material can be a sintered material, such as sintered silver or sintered copper. In some embodiments, the die-attach material comprises an electroless deposited material, such as copper or nickel. In some embodiments, the die-attach material may be a eutectic alloy, such as an Au—Sn alloy, or an Au—Sn—Co alloy. Other suitable die-attach materials may be used without deviating from the scope of the present disclosure.

In some embodiments, the second structure 204 comprises a semiconductor die or a submount and the second surface 208 comprises a conductive catalytic layer. The catalytic layer may comprise, for example, at least one of gold (Au), palladium (Pd), nickel (Ni), or aluminum (Al). In such embodiments, the adhesion promoting layer 210 can be disposed between the conductive catalytic layer and first structure 202, which can be an encapsulating material.

In some embodiments, the first structure 202 comprises an encapsulating material and the second structure 204 comprises a submount, such as a copper lead frame, a clip structure, a DBC substrate, etc.

In some embodiments, the first structure 202 comprises an encapsulating material and the second structure 204 comprises a semiconductor die. In some embodiments, the semiconductor die comprises silicon carbide or a Group III nitride.

The adhesion promoting layer 210 comprises the polyimide described above. More specifically, the polyimide generally comprises repeating units derived from a tetracarboxylic dianhydride and at least one diamine containing a functional group.

The tetracarboxylic dianhydride is not limited and can comprise any suitable tetracarboxylic dianhydride known in the art. For example, in some embodiments, the tetracarboxylic dianhydride is a tetracarboxylic dianhydride having a structure having at least one benzene ring, in which two carboxylic anhydride groups are bonded to the one benzene ring. Such embodiments include, for example, tetracarboxylic dianhydrides represented by the following formulae (TD11) and (TD12).

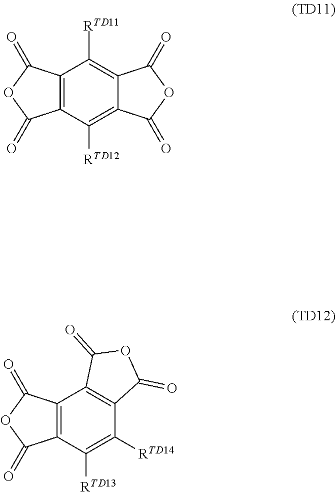

In the formulae (TD11) and (TD12), R^{TD11}, R^{TD12}, R^{TD13}, and R^{TD14} each independently represent a hydrogen atom, a carboxyl group, a substituted or unsubstituted alkyl group, or a substituted or unsubstituted phenyl group.

In the formulae (TD11) and (TD12), examples of the alkyl group represented by R^{TD11} to R^{TD14} include ones having 1 to 12 (preferably 1 to 6) carbon atoms. The alkyl group may be chained or cyclic; in a case where the alkyl group is chained, it may be linear or branched; and in a case where the alkyl group is cyclic, it may be monocyclic or polycyclic (for example, bicyclic, tricyclic, and a spiro ring). Examples of the alkyl group include a methyl group, an ethyl group, an n-propyl group, an isopropyl group, a cyclopropyl group, an n-butyl group, an isobutyl group, a sec-butyl group, a tert-butyl group, a cyclobutyl group, an n-pentyl group, an isopentyl group, a neopentyl group, a tert-pentyl group, a cyclopentyl group, an n-hexyl group, an isohexyl group, a sec-hexyl group, a tert-hexyl group, a cyclohexyl group, an n-heptyl group, an isoheptyl group, a sec-heptyl group, a tert-heptyl group, a cycloheptyl group, an n-octyl group, an isooctyl group, a sec-octyl group, a tert-octyl group, a cyclooctyl group, an n-nonyl group, an isononyl group, a sec-nonyl group, a tert-nonyl group, a cyclononyl group, an n-decyl group, an isodecyl group, a sec-decyl group, a tert-decyl group, and a cyclodecyl group. Examples of the substituent which is substituted on the alkyl group include a hydroxyl group, a carboxyl group, and a cyano group.

In the formulae (TD11) and (TD12), examples of the substituent which is substituted on a phenyl group represented by R^{TD11} to R^{TD14} include a hydroxyl group, a carboxyl group, and a cyano group.

Suitable examples of the tetracarboxylic dianhydride represented by the formula (TD11) include tetracarboxylic dianhydrides, in which R^{TD11} represents a hydrogen atom, a methyl group, a phenyl group, or a carboxyl group, and R^{TD12} represents a hydrogen atom, a methyl group, a phenyl group, or a carboxyl group.

Suitable examples of the tetracarboxylic dianhydride represented by the formula (TD12) include tetracarboxylic dianhydrides, in which R^{TD13} represents a hydrogen atom, a methyl group, a phenyl group, or a carboxyl group, and R^{TD14} represents a hydrogen atom, a methyl group, a phenyl group, or a carboxyl group.

Specific examples of such dianhydrides include pyromellitic dianhydride, methylpyromellitic dianhydride, dimethylpyromellitic dianhydride, ethylpyromellitic dianhydride, diethylpyromellitic dianhydride, phenylpyromellitic dianhydride, diphenylpyromellitic dianhydride, 1,2,3,4,5-benzenepentacarboxylic 1,2,4,5-dianhydride, 1,2,3,4,5-benzenepentacarboxylic 1,2,3,4-dianhydride, benzenehexacarboxylic 1,2,4,5-dianhydride, and benzenehexacarboxylic 1,2,3,4-dianhydride.

Other examples of the tetracarboxylic dianhydride have two benzene rings to which one carboxylic anhydride group is bonded. More specifically, the tetracarboxylic dianhydride can be a tetracarboxylic dianhydride having at least two benzene rings, in which one carboxylic anhydride group is bonded to one benzene ring of the two benzene rings and one carboxylic anhydride group is bonded to the other benzene ring. Such tetracarboxylic dianhydrides include those represented by the following formulae (TD21) and (TD22).

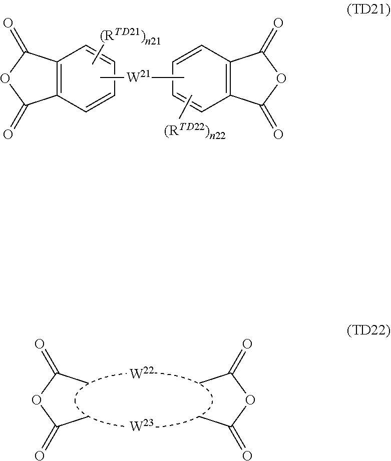

In the formula (TD21), R^{TD21} and R^{TD22} each independently represent a substituted or unsubstituted alkyl group or a substituted or unsubstituted phenyl group. Here, the details of the substituted or unsubstituted alkyl group or the substituted or unsubstituted phenyl group represented by R^{TD21} and R^{TD22} are the same as the substituted or unsubstituted alkyl group or the substituted or unsubstituted phenyl group represented by R^{TD11} to R^{TD14} in the formulae (TD11) and (TD12).
n21 and n22 each independently represent 0, or an integer of 1 to 3.
W²¹ represents a single bond, or any one group of the following 1) to 8):
1) —C(═O)—, —C(═O)—O—, —C(═O)NH—, or —O—;
2) an alkylene group (for example, an alkylene group having 1 to 12 carbon atoms);
3) a fluoroalkylene group (for example, an alkylene group having 1 to 12 carbon atoms, having at least one hydrogen atom substituted with a fluorine atom);
4) —Si(—R^{TD23})(—R^{TD24})— (in which R^{TD23} and R^{TD24} each independently represent an alkyl group (for example, an alkyl group having 1 to 3 carbon atoms), an aryl group (for example, a phenyl group and a naphthyl group), or an alkoxy group);
5) —O—Ph—R^{TD25}Ph-O— (in which Ph represents a phenylene group, and R^{TD25} represents —S—S—, —S(═O)₂, an ester group, or an amide group);
6) —P(═O)(—R^{TD26})— (in which R^{TD26} represents an aryl group (for example, a phenyl group), an ester group, or an amide group);
7) —C(—Ph^{A})(—Ph^{A})—Ph—R^{TD27}—Ph—C(—Ph^{A})(—Ph^{A})(in which Ph represents a phenylene group, Ph^{A} represents a phenyl group, and R^{TD27},s each independently represent —O—, an alkyl group (for example, an alkyl group having 1 to 6 carbon atoms), or an aryl group (for example, a phenyl group and a naphthyl group)); and
8) —O—(—R^{TD28})—O— (in which R^{TD28} represents an alkylene group (for example, an alkylene group having 1 to 12 carbon atoms)).

In the formula (TD22), W²² and W²³ represent atomic groups which are bonded to each other to form a substituted or unsubstituted condensed aromatic ring (for example, a naphthalene ring, a pyrene ring, and an anthracene ring), or a substituted or unsubstituted heterocycle (for example, a furan ring, a pyridine ring, and an imidazole ring).

Examples of the substituent which substitutes a condensed aromatic ring or a heterocycle include an alkyl group and a carboxyl group.

Suitable examples of the tetracarboxylic dianhydride represented by the formula (TD21) include tetracarboxylic dianhydrides, in which n21 and n22 represent 0 and W²¹ represents —C(═O)— or an alkylene group (for example, an alkylene group having 1 to 6 carbon atoms).

Suitable examples of the tetracarboxylic dianhydride represented by the formula (TD22) include tetracarboxylic dianhydrides, in which W²² and W²³ represent atomic groups which are bonded to each other to form a naphthalene ring, a furan ring, a pyrene ring, and an anthracene ring.

Examples of such aromatic tetracarboxylic dianhydrides include 3,3′,4,4′-benzophenonetetracarboxylic dianhydride, 3,3′,4,4′-biphenylsulfonetetracarboxylic dianhydride, 1,4,5,8-naphthalenetetracarboxylic dianhydride, 2,3,6,7-naphthalenetetracarboxylic dianhydride, 3,3′,4,4′-biphenyl ether tetracarboxylic dianhydride, 3,3′,4,4′-dimethyldiphenylsilanetetracarboxylic dianhydride, 3,3′,4,1′-tetraphenylsilanetetracarboxylic dianhydride, 1,2,3,4-furantetracarboxylic dianhydride, 4,4′-bis(3,4-dicarboxyphenoxy)diphenylsulfide dianhydride, 4,4′-bis(3,4-dicarboxyphenoxy)diphenylsulfone dianhydride, 4,4′-bis(3,4-dicarboxyphenoxy)diphenylpropane dianhydride, 3,3,4,4′-perfluoroisopropylidene diphthalic dianhydride, 3,3′,4,4′-biphenyltetracarboxylic dianhydride, 2,3,3′,4′-biphenyltetracarboxylic dianhydride, bis(phthalic acid)phenylphosphine oxide dianhydride, p-phenylene-bis(triphenylphthalic)dianhydride, m-phenylene-bis(triphenylphthalic)dianhydride, bis(triphenylphthalic acid)-4,4′-diphenyl ether dianhydride, and bis(triphenylphthalic acid)-4,4′-diphenylmethane dianhydride.

Examples of such aliphatic tetracarboxylic dianhydrides include aliphatic or alicyclic tetracarboxylic dianhydrides such as butanetetracarboxylic dianhydride, 1,2,3,4-cyclobutanetetracarboxylic dianhydride, 1,3-dimethyl-1,2,3,4-cyclobutanetetracarboxylic acid, 1,2,3,4-cyclopentanetetracarboxylic dianhydride, 2,3,5-tricarboxycyclopentylacetic dianhydride, 3,5,6-tricarboxynorbornane-2-acetic dianhydride, 2,3,4,5-tetrahydrofurantetracarboxylic dianhydride, 5-(2,5-dioxotetrahydrofuran))-3-methyl-3-cyclohexene-1,2-dicarboxylic dianhydride, and bicyclo[2,2,2]-oct-7-ene-2,3,5,6-tetracarboxylic dianhydride; and aliphatic tetracarboxylic dianhydrides having an aromatic ring, such as 1,3,3a,4,5,9b-hexahydro-2,5-dioxo-3-furanyl)-naphtho[1,2-c]furan-1,3-dione, 1,3,3a,4,5,9b-hexahydro-5-methyl-5-(tetrahydro-2,5-dioxo-3-furanyl)-naphtho[1,2-c]furan-1,3-dione, and 1,3,3a,4,5,9b-hexahydro-8-methyl-5-(tetrahydro-2,5-dioxo-3-furanyl)-naphtho[1,2-c]furan-1,3-dione.

As described above, the polyimide also contains structural groups derived from at least one diamine containing a function group. In some embodiments, the functional group is an azole, for example, an oxazole or an imidazole. In some embodiments, the polyimide contains structural units derived from both a diamine benzoxazole and a diamine benzimidazole. In other embodiments, the diamine can contain other functional groups, such as glycidyl epoxide, aliphatic amine, or silane groups. Such functional groups may be contained alone or in addition to azole groups.

Exemplary diamine benzoxazoles include the following:

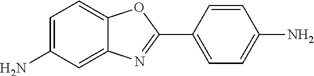 [SMILES: Nc1ccc(-c2nc3cc(N)ccc3o2)cc1]

2-(4-aminophenyl)benzo[d]oxazol-5-amine;

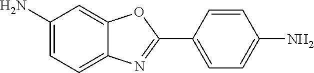 [SMILES: Nc1ccc(-c2nc3ccc(N)cc3o2)cc1]

2-(4-aminophenyl)benzo[d]oxazol-6-amine;

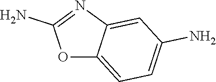 [SMILES: Nc1ccc2oc(N)nc2c1]

benzo[d]oxazole-2,5-diamine;

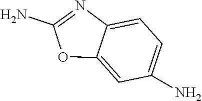 [SMILES: Nc1ccc2nc(N)oc2c1]

benzo[d]oxazole-2,6-diamine; or combinations thereof.

Exemplary diamine benzimidazoles include the following:

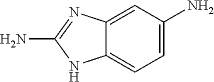 [SMILES: Nc1ccc2[nH]c(N)nc2c1]

1H-benzo[d]imidazole-2,5-diamine;

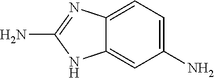 [SMILES: Nc1ccc2nc(N)[nH]c2c1]

1H-benzo[d]imidazole-2,6-diamine;

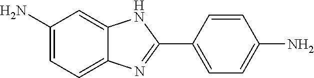 [SMILES: Nc1ccc(-c2nc3ccc(N)cc3[nH]2)cc1]

2-(4-aminophenyl)-1H-benzo[d]imidazol-5-amine;

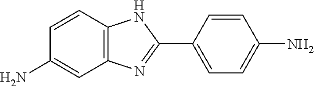 [SMILES: Nc1ccc(-c2nc3cc(N)ccc3[nH]2)cc1]

2-(4-aminophenyl)-1H-benzo[d]imidazol-6-amine; or combinations thereof.

In some embodiments, the tetracarboxylic dianhydride is selected from one or more of pyromellitic dianhydride, 3,3′,4,4′-benzophenonetetracarboxylic dianhydride, bicyclo[2,2,2]-oct-7-ene-2,3,5,6-tetracarboxylic dianhydride, and 3,3′,4,4′-biphenyltetracarboxylic dianhydride; the diamine benzoxazole is selected from benzo[d]oxazole-2,5-diamine and/or 2-(4-aminophenyl)benzo[d]oxazol-5-amine; and the diamine benzimidazole is selected from 1H-benzo[d]imidazole-2,5-diamine and/or 2-(4-aminophenyl)-1H-benzo[d]imidazol-6-amine. In some embodiments, for example, the polyimide comprises units derived from bicyclo[2,2,2]-oct-7-ene-2,3,5,6-tetracarboxylic dianhydride, benzo[d]oxazole-2,5-diamine, and 1H-benzo[d]imidazole-2,5-diamine. The present inventors found that the use of bicyclo[2,2,2]-oct-7-ene-2,3,5,6-tetracarboxylic dianhydride provides higher solubility in polar solvents as well as superior thermomechanical properties compared to other commonly used tetracarboxylic dianhydrides.

In some embodiments, when the polyimide contains repeating units derived from both a diamine benzoxazole and a diamine benzimidazole, the molar ratio of the repeating units derived from the diamine benzoxazole to the repeating units derived from the diamine benzimidazole can be from about 30:70 to about 70:30, in some embodiments from about 30:70 to about 50:50, and in some embodiments, from about 35:65 to about 45:55. The molar ratio may be adjusted based on the properties of the surfaces in contact with the adhesion promoting layer.

The thickness of the adhesion promoting layer 210 is not limited, but in some embodiments is relatively thin, such as from about 2 μm to about 25 μm.

The polyimide can be produced in any manner known in the art. In some embodiments, for example, the polyimide is made by a “two-pot” process. In such embodiments, a first polyimide precursor is formed in one vessel and a second polyimide precursor is formed in a second vessel. The two polyimide precursors are then mixed together to form a polyamic acid mixture which can be cured into the polyimide.

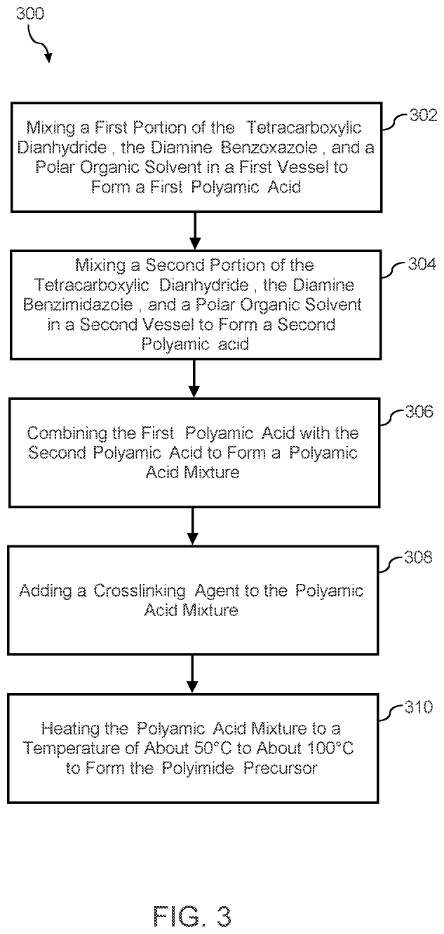

FIG. 3 depicts a flow chart diagram of an example method 300 according to example embodiments of the present disclosure. FIG. 3 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At (302), method 300 may comprise mixing a first portion of a tetracarboxylic dianhydride, a diamine benzoxazole, and a polar organic solvent in a first vessel to form a first polyamic acid. At (304), method 300 may comprise mixing a second portion of the tetracarboxylic dianhydride, a diamine benzimidazole, and a polar organic solvent in a second vessel to form a second polyamic acid. In each vessel, the molar ratio of tetracarboxylic dianhydride and diamine may be generally from about 0.7 to about 1.3, in some embodiments from about 0.9 to about 1.1, and in some embodiments, about 1. The molar ratio of the first polyamic acid to the second polyamic acid can be selectively controlled based on the desired proportion of each functional group within the resulting polyimide. For example, as explained above, the molar ratio of the repeating units derived from the diamine benzoxazole to the repeating units derived from the diamine benzimidazole is from about 30:70 to about 70:30, in some embodiments from about 30:70 to about 50:50, and in some embodiments, from about 35:65 to about 45:55.

The tetracarboxylic dianhydride used in the first vessel may be the same or different as the tetracarboxylic dianhydride used in the second vessel. The polar organic solvent used in each vessel can be any such solvent known in the art. For example, N-methyl-2-pyrrolidone (NMP), N,N-dimethylformamide (DMF), N,N-dimethylacetamide (DMAc), dimethylsulfoxide (DMSO), hexanemethylenephosphoramide (HMPA), N-methylcaprolactam, tetramethylurea, hexamethylphosphoric triamide, γ-butyrolactone, and/or N-acetyl-2-pyrrolidone may be used as the solvent. The relative concentration of the monomers within the solvent can be selected based on the desired molecular weight, as is known in the art. The first and second polyamic acids can be prepared at ambient temperature.

At (306), method 300 may comprise combining the first polyamic acid and the second polyamic acid to form a polyamic acid mixture. At (308), method 300 may comprise optionally adding a crosslinking agent to the polyamic acid mixture. It will be understood that the addition of a crosslinking agent is not necessary and can be omitted. When employed, the crosslinking agent may comprise, for example, hexamethylenediamine, p-xylylenediamine, ethylenediamine, polyethyleneimine, diethyltriamine, and/or dimethylethyldiamine. The molar ratio of the crosslinking agent to the polyimide precursor may be from about 0.1 to about 0.3.

At (310), method 300 may comprise heating the polyamic acid mixture to a temperature from about 50° C. to about 100° C. to form the polyimide precursor. The mixture may be stirred for any suitable time, for example, from about 12 to 48 hours. In some embodiments, the heating and stirring may be performed under a purge of an inert gas (e.g., Ar, N₂, etc.). It will be understood that when a crosslinking agent is added, it can be added before, during, or after stirring the mixture.

In other embodiments, a “single pot” process may be used to prepare the polyimide precursor. In such embodiments, the tetracarboxylic dianhydride is mixed with the functionalized diamine in a single vessel. The functionalized diamine may comprise a mixture of different diamines (e.g., a diamine benzoxazole and a diamine benzimidazole).

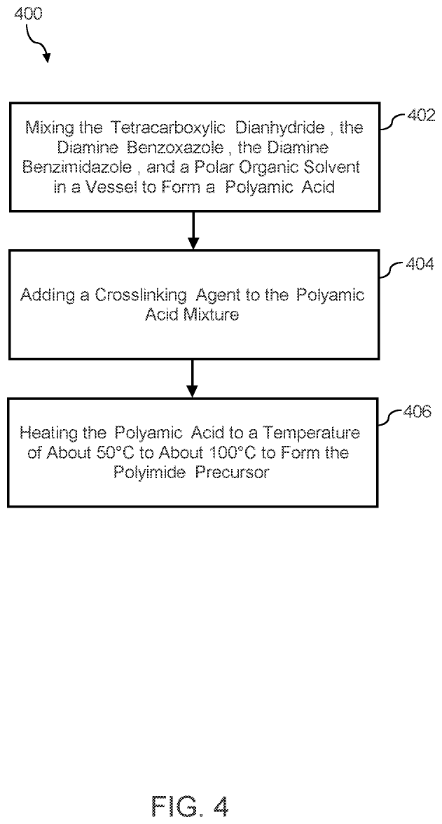

FIG. 4 depicts a flow chart diagram of an example method 400 according to example embodiments of the present disclosure. FIG. 4 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At (402), method 400 may comprise mixing a tetracarboxylic dianhydride, a diamine benzoxazole, a diamine benzimidazole, and a polar organic solvent in a vessel to form a polyamic acid. The polar organic solvent may be as described above with respect to method 300. The mixture can be formed at ambient temperature.

The molar ratio of the tetracarboxylic dianhydride to the total diamine (diamine benzoxazole and diamine benzimidazole) may be from about 0.7 to about 1.3, in some embodiments from about 0.9 to about 1.1, and in some embodiments, about 1.

The molar ratio of the diamine benzoxazole to the diamine benzimidazole can be selectively controlled based on the desired proportion of each functional group within the resulting polyimide. For example, as explained above, the molar ratio of the repeating units derived from the diamine benzoxazole to the repeating units derived from the diamine benzimidazole is from about 30:70 to about 70:30, in some embodiments from about 30:70 to about 50:50, and in some embodiments, from about 35:65 to about 45:55.

At (404), method 400 may comprise optionally adding a crosslinking agent to the polyamic acid. It will be understood that the addition of a crosslinking agent is not necessary and can be omitted. When employed, the crosslinking agent may comprise, for example, hexamethylenediamine, p-xylylenediamine, ethylenediamine, polyethyleneimine, diethyltriamine, and/or dimethylethyldiamine. The molar ratio of the crosslinking agent to the polyimide precursor may be from about 0.1 to about 0.3.

At (406), method 400 may comprise heating the polyamic acid may to a temperature from about 50° C. to about 100° C. to form the polyimide precursor. The mixture may be stirred for any suitable time, for example, from about 12 to 48 hours. In some embodiments, the heating and stirring may be performed under a purge of an inert gas (e.g., Ar, N₂, etc.). It will be understood that when a crosslinking agent is added, it can be added before, during, or after stirring the polyamic acid.

Once a polyimide precursor is formed (e.g., by the one-pot or two-pot processes described above), it may be coated onto a surface within a semiconductor device package where it can be cured into a polyimide film acting as an adhesion promoting layer.

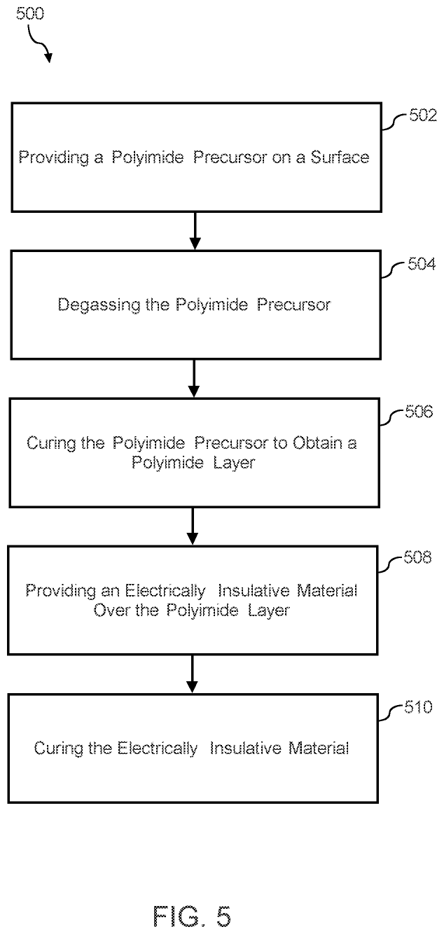

FIG. 5 depicts a flow chart diagram of an example method 500 according to example embodiments of the present disclosure. FIG. 5 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At (502), method 500 may include providing a polyimide precursor on a surface. The surface can comprise any one or more of the surfaces described above with respect to FIG. 2. For example, the surface can be the top surface of a semiconductor die and the outer surface of a lead frame. The polyimide precursor can be provided on the surface by any suitable method. In some embodiments, for example, the polyimide precursor can be applied to the target surface by spin coating, spray coating, and/or dip coating. The thickness of the precursor coating can be controlled as desired depending on the desired thickness of the resulting polyimide adhesion layer. For example, as described above, it may be controlled to be from about 2 μm to about 25 μm.

At (504), method 500 may comprise degassing the polyimide precursor. Degassing can reduce the presence of bubbles within the resulting polyimide film. In some embodiments, degassing comprises heating the precursor to a temperature of from about 50° C. to about 100° C. for a suitable time period, for example, from about 30 min to about 60 min. During the degassing process, a partial imidization can occur which can mitigate voids, shrinkage, and stress formation in the final coating since water, which is given off during the cyclization process, will be present at lower levels during the final coating process. It will be understood that degassing is an optional step and can be omitted.

At (506), method 500 may include curing the polyimide precursor to form a polyimide layer. Curing, also known as imidization or cyclization, can be achieved by heating the polyimide precursor layer. For example, in some embodiments, the precursor can be heated to a temperature of from about 150° C. to about 400° C., such as about 250° C. to about 350° C. for a suitable time period, for example, from about 1 hour to about 2 hours. In some embodiments, the polyimide precursor can be gradually heated to the desired temperature. In other embodiments, the polyimide precursor can be heated to about 100° C. and held for about an hour, heated from 100° C. to 200° C. and held for about an hour, heated from 200° C. to 300° C. and held for about one hour, and slowly cooled to room temperature from 300° C. In some embodiments, the curing atmosphere is an inert atmosphere, such as a nitrogen gas atmosphere or a nitrogen/hydrogen mixed gas atmosphere. In other embodiments, curing may be conducting an air atmosphere or under vacuum.

At (508), method 500 may comprise providing an electrically insulative material over the polyimide layer. In some embodiments, the electrically insulative material may comprise an epoxy molding compound, as is known in the art. For example, in some embodiments, an epoxy molding compound may be deposited over the semiconductor die and at least a portion of the lead frame (including over the adhesion promoting polyimide layer) by paste printing, compressive molding, transfer molding, liquid encapsulant molding, vacuum lamination, spin coating, or any other suitable application method. The insulative material environmentally protects the semiconductor device from external elements and contaminants.

At (510), method 500 may include curing the electrically insulative material (e.g., epoxy molding compound). The electrically insulative material may be cured by any means known in the art. For example, an epoxy molding compound may be cured by heating at a temperature from about 130° C. to about 200° C., such as about 150° C. to about 180° C., for a suitable time period, for example, from about 1 to about 10 minutes.

Example aspects of the present disclosure are set forth below. Any of the below features or examples may be used in combination with any of the embodiments or features provided in the present disclosure.

One example embodiment of the present disclosure is directed to a semiconductor device package. The semiconductor device package comprises a first structure having a first surface in the semiconductor device package, a second structure having a second surface in the semiconductor device package, and an adhesion promoting layer in contact with the first surface on a first side and the second surface on a second side. The adhesion promoting layer comprises a polyimide containing repeating units derived from a tetracarboxylic dianhydride and at least one diamine containing a functional group.

In some examples, the tetracarboxylic dianhydride is represented by the following formula (TD11) or (TD12):

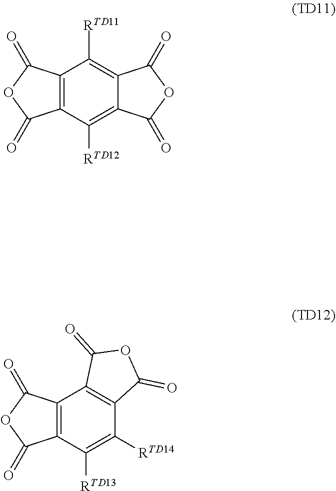

wherein R^{TD11}, R^{TD12}, R^{TD13}, and R^{TD14} each independently represent a hydrogen atom, a carboxyl group, a substituted or unsubstituted alkyl group, or a substituted or unsubstituted phenyl group.

In some examples, the tetracarboxylic dianhydride comprises pyromellitic dianhydride, methylpyromellitic dianhydride, dimethylpyromellitic dianhydride, ethylpyromellitic dianhydride, diethylpyromellitic dianhydride, phenylpyromellitic dianhydride, diphenylpyromellitic dianhydride, 1,2,3,4,5-benzenepentacarboxylic 1,2,4,5-dianhydride, 1,2,3,4,5-benzenepentacarboxylic 1,2,3,4-dianhydride, benzenehexacarboxylic 1,2,4,5-dianhydride, and benzenehexacarboxylic 1,2,3,4-dianhydride, or a combination thereof.

In some examples, the tetracarboxylic dianhydride is represented by the following formula (TD21) or (TD22):

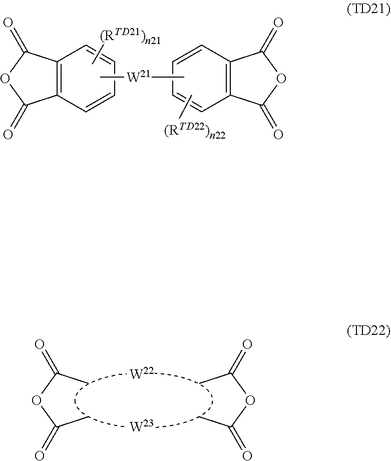

wherein R^{TD21} and R^{TD22} each independently represent a hydrogen atom, a carboxyl group, a substituted or unsubstituted alkyl group, or a substituted or unsubstituted phenyl group;
n21 and n22 each independently represent 0, or an integer of 1 to 3;
W²¹ represents a single bond, or any one group of the following 1) to 8):
1) —C(═O)—, —C(═O)—O—, —C(═O)—NH—, or —O—;
2) an alkylene group (for example, an alkylene group having 1 to 12 carbon atoms);
3) a fluoroalkylene group (for example, an alkylene group having 1 to 12 carbon atoms, having at least one hydrogen atom substituted with a fluorine atom);
4) —Si(—R^{TD23})(—R^{TD24})— (in which R^{TD23} and R^{TD24} each independently represent an alkyl group (for example, an alkyl group having 1 to 3 carbon atoms), an aryl group (for example, a phenyl group and a naphthyl group), or an alkoxy group);
5) —O—Ph—R^{TD25}—Ph-O— (in which Ph represents a phenylene group, and R^{TD25} represents —S—S—, —S(═O)₂—, an ester group, or an amide group);
6) —P(═O)(—R^{TD26})— (in which R^{TD26} represents an aryl group (for example, a phenyl group), an ester group, or an amide group);
7) —C(—Ph^{A})(—Ph^{A})—Ph—R^{TD27}—Ph—C(—Ph^{A})(—Ph^{A})— (in which Ph represents a phenylene group, Ph^{A} represents a phenyl group, and R^{TD27}'s each independently represent 0, an alkyl group (for example, an alkyl group having 1 to 6 carbon atoms), or an aryl group (for example, a phenyl group and a naphthyl group)); and
8) —O—(—R^{TD28})—O— (in which R^{TD28} represents an alkylene group (for example, an alkylene group having 1 to 12 carbon atoms)); and
W²² and W²³ represent atomic groups which are bonded to each other to form a substituted or unsubstituted condensed aromatic ring or a substituted or unsubstituted heterocycle.

In some examples, the tetracarboxylic dianhydride comprises 3,3′,4,4′-benzophenonetetracarboxylic dianhydride, 3,3′,4,4′-biphenylsulfonetetracarboxylic dianhydride, 1,4,5,8-naphthalenetetracarboxylic dianhydride, 2,3,6,7-naphthalenetetracarboxylic dianhydride, 3,3′,4,4′-biphenyl ether tetracarboxylic dianhydride, 3,3′,4,4′-dimethyldiphenylsilanetetracarboxylic dianhydride, 3,3′,4,4′-tetraphenylsilanetetracarboxylic dianhydride, 1,2,3,4-furantetracarboxylic dianhydride, 4,4′-bis(3,4-dicarboxyphenoxy)diphenylsulfide dianhydride, 4,4′-bis(3,4-dicarboxyphenoxy)diphenylsulfone dianhydride, 4,4′-bis(3,4-dicarboxyphenoxy)diphenylpropane dianhydride, 3,3,4,4′-perfluoroisopropylidene diphthalic dianhydride, 3,3′,4,4′-biphenyltetracarboxylic dianhydride, 2,3,3′,4′-biphenyltetracarboxylic dianhydride, bis(phthalic acid)phenylphosphine oxide dianhydride, p-phenylene-bis(triphenylphthalic)dianhydride, m-phenylene-bis(triphenylphthalic)dianhydride, bis(triphenylphthalic acid)-4,4′-diphenyl ether dianhydride, bis(triphenylphthalic acid)-4,4′-diphenylmethane dianhydride, butanetetracarboxylic dianhydride, 1,2,3,4-cyclobutanetetracarboxylic dianhydride, 1,3-dimethyl-1,2,3,4-cyclobutanetetracarboxylic acid, 1,2,3,4-cyclopentanetetracarboxylic dianhydride, 2,3,5-tricarboxycyclopentylacetic dianhydride, 3,5,6-tricarboxynorbornane-2-acetic dianhydride, 2,3,4,5-tetrahydrofurantetracarboxylic dianhydride, 5-(2,5-dioxotetrahydrofuran))-3-methyl-3-cyclohexene-1,2-dicarboxylic dianhydride, and bicyclo[2,2,2]-oct-7-ene-2,3,5,6-tetracarboxylic dianhydride; and aliphatic tetracarboxylic dianhydrides having an aromatic ring, such as 1,3,3a,4,5,9b-hexahydro-2,5-dioxo-3-furanyl)-naphtho[1,2-c]furan-1,3-dione, 1,3,3a,4,5,9b-hexahydro-5-methyl-5-(tetrahydro-2,5-dioxo-3-furanyl)-naphtho[1,2-c]furan-1,3-dione, 1,3,3a,4,5,9b-hexahydro-8-methyl-5-(tetrahydro-2,5-dioxo-3-furanyl)-naphtho[1,2-c]furan-1,3-dione, or any combination thereof.

In some examples, the functional group is an azole.

In some examples, the azole is an oxazole or an imidazole.

In some examples, the at least one diamine comprises a diamine benzoxazole and/or a diamine benzimidazole.

In some examples, the at least one diamine comprises a diamine benzoxazole and a diamine benzimidazole.

In some examples, the diamine benzoxazole comprises benzo[d]oxazole-2,5-diamine, benzo[d]oxazole-2,6-diamine, 2-(4-aminophenyl)benzo[d]oxazol-5-amine, 2-(4-aminophenyl)benzo[d]oxazol-6-amine, or a combination thereof.

In some examples, the diamine benzimidazole comprises 1H-benzo[d]imidazole-2,5-diamine, 1H-benzo[d]imidazole-2,6-diamine, 2-(4-aminophenyl)-1H-benzo[d]imidazol-5-amine, 2-(4-aminophenyl)-1H-benzo[d]imidazol-6-amine, or a combination thereof.

In some examples, a molar ratio of the repeating units derived from the diamine benzoxazole to the repeating units derived from the diamine benzimidazole is from about 30:70 to about 70:30.

In some examples, a molar ratio of the repeating units derived from the diamine benzoxazole to the repeating units derived from the diamine benzimidazole is from about 30:70 to about 50:50.

In some examples, a molar ratio of the repeating units derived from the diamine benzoxazole to the repeating units derived from the diamine benzimidazole is from about 35:65 to about 45:55.

In some examples, the adhesion promoting layer has a thickness from about 2 μm to about 25 μm.

In some examples, the first structure comprises an electrically insulative material.

In some examples, the first surface comprises an epoxy resin.

In some examples, the second structure comprises an electrically conductive material.

In some examples, the second structure is a semiconductor structure.

In some examples, the second surface comprises copper, copper(II) oxide, and/or copper(II) hydroxide.

In some examples, the second surface comprises nickel, nickel(II) oxide, and/or nickel(II) hydroxide.

In some examples, the second surface comprises aluminum, aluminum oxide, and/or aluminum hydroxide.

In some examples, the second surface comprises hydrogenated silicon oxide.

In some examples, the second surface comprises silicon nitride.

In some examples, the second surface comprises silicon carbide.

In some examples, the second surface comprises a Pb—Sn alloy.

In some examples, the second surface comprises gold.

In some examples, the second surface comprises silver.

In some examples, the second surface comprises an organic material.

In some examples, the organic material comprises a polyimide.

In some examples, the semiconductor device package comprises a wide bandgap semiconductor device.

In some examples, the wide bandgap semiconductor device comprises a silicon carbide-based MOSFET, a silicon carbide-based Schottky diode, or a Group III nitride-based high electron mobility transistor.

Another example embodiment of the present disclosure is directed to a semiconductor device package. The semiconductor device package comprises a semiconductor die comprising a wide bandgap semiconductor device, a submount, a die-attach material coupling the semiconductor die to the submount, an encapsulating material, and an adhesion promoting layer. The adhesion promoting layer comprises a polyimide containing repeating units derived from a tetracarboxylic dianhydride, a diamine benzoxazole, and a diamine benzimidazole.

In some examples, the adhesion promoting layer is disposed between the encapsulating material and the die-attach material.

In some examples, the die-attach material comprises a sintered material.

In some examples, the sintered material comprises sintered silver or sintered copper.

In some examples, the die-attach material comprises an electroless deposited material.

In some examples, the electroless deposited material comprises copper.

In some examples, the electroless deposited material comprises nickel.

In some examples, the semiconductor device package further comprises a conductive catalytic layer on the semiconductor die or on the submount.

In some examples, the adhesion promoting layer is disposed between the conductive catalytic layer and the encapsulating material.

In some examples, the conductive catalytic layer comprises at least one of gold, palladium, nickel, or aluminum.

In some examples, the adhesion promoting layer is disposed between the submount and the encapsulating material.

In some examples, the submount comprises a lead frame.

In some examples, the submount comprises copper.

In some examples, the adhesion promoting layer is disposed between the semiconductor die and the encapsulating material.

In some examples, the semiconductor die comprises silicon carbide or a Group III nitride.

In some examples, the wide bandgap semiconductor device comprises a silicon carbide-based MOSFET, a silicon carbide-based Schottky diode, or a Group III nitride-based high electron mobility transistor.

In some examples, the encapsulating material comprises an epoxy resin.

In some examples, the tetracarboxylic dianhydride is represented by the following formula (TD11) or (TD12):

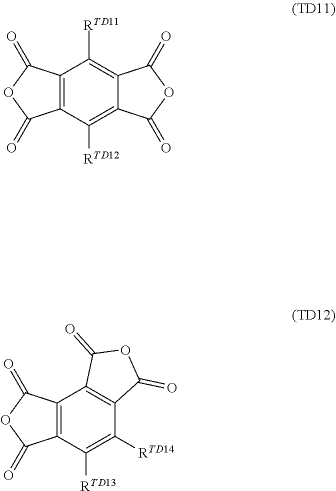

wherein R^{TD11}, R^{TD12}, R^{TD13}, and R^{TD14} each independently represent a hydrogen atom, a carboxyl group, a substituted or unsubstituted alkyl group, or a substituted or unsubstituted phenyl group.

In some examples, the tetracarboxylic dianhydride comprises pyromellitic dianhydride, methylpyromellitic dianhydride, dimethylpyromellitic dianhydride, ethylpyromellitic dianhydride, diethylpyromellitic dianhydride, phenylpyromellitic dianhydride, diphenylpyromellitic dianhydride, 1,2,3,4,5-benzenepentacarboxylic 1,2,4,5-dianhydride, 1,2,3,4,5-benzenepentacarboxylic 1,2,3,4-dianhydride, benzenehexacarboxylic 1,2,4,5-dianhydride, and benzenehexacarboxylic 1,2,3,4-dianhydride, or a combination thereof.

In some examples, the tetracarboxylic dianhydride is represented by the following formula (TD21) or (TD22):

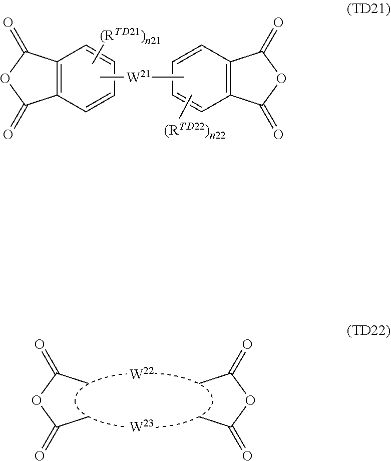

wherein R^{TD21} and R^{TD22} each independently represent a hydrogen atom, a carboxyl group, a substituted or unsubstituted alkyl group, or a substituted or unsubstituted phenyl group;
n21 and n22 each independently represent 0, or an integer of 1 to 3;
W²¹ represents a single bond, or any one group of the following 1) to 8):
1) —C(═O)—, —C(═O)—O—, —C(═O)—NH—, or —O—;
2) an alkylene group (for example, an alkylene group having 1 to 12 carbon atoms);
3) a fluoroalkylene group (for example, an alkylene group having 1 to 12 carbon atoms, having at least one hydrogen atom substituted with a fluorine atom);
4) —Si(—R^{TD23})(—R^{TD24})— (in which R^{TD23} and R^{TD24} each independently represent an alkyl group (for example, an alkyl group having 1 to 3 carbon atoms), an aryl group (for example, a phenyl group and a naphthyl group), or an alkoxy group);
5) —O—Ph—R^{TD25}—Ph—O— (in which Ph represents a phenylene group, and R^{TD25} represents —S—S—, (═O)₂, an ester group, or an amide group);
6) —P(═O)(—R^{TD26})— (in which R^{TD26} represents an aryl group (for example, a phenyl group), an ester group, or an amide group);
7) —C(—Ph^{A})(—Ph^{A})—Ph—R^{TD27}—Ph—C(—Ph^{A})(—Ph^{A})(in which Ph represents a phenylene group, Ph^{A} represents a phenyl group, and R^{TD27}'s each independently represent —O—, an alkyl group (for example, an alkyl group having 1 to 6 carbon atoms), or an aryl group (for example, a phenyl group and a naphthyl group)); and
8) —O—(—R^{TD28})—O— (in which R^{TD28} represents an alkylene group (for example, an alkylene group having 1 to 12 carbon atoms)); and
W²² and W²³ represent atomic groups which are bonded to each other to form a substituted or unsubstituted condensed aromatic ring or a substituted or unsubstituted heterocycle.

In some examples, the tetracarboxylic dianhydride comprises 3,3′,4,4′-benzophenonetetracarboxylic dianhydride, 3,3′,4,4′-biphenylsulfonetetracarboxylic dianhydride, 1,4,5,8-naphthalenetetracarboxylic dianhydride, 2,3,6,7-naphthalenetetracarboxylic dianhydride, 3,3′,4,4′-biphenyl ether tetracarboxylic dianhydride, 3,3′,4,4′-dimethyldiphenylsilanetetracarboxylic dianhydride, 3,3′,4,4′-tetraphenylsilanetetracarboxylic dianhydride, 1,2,3,4-furantetracarboxylic dianhydride, 4,4′-bis(3,4-dicarboxyphenoxy)diphenylsulfide dianhydride, 4,4′-bis(3,4-dicarboxyphenoxy)diphenylsulfone dianhydride, 4,4′-bis(3,4-dicarboxyphenoxy)diphenylpropane dianhydride, 3,3,4,4′-perfluoroisopropylidene diphthalic dianhydride, 3,3′,4,4′-biphenyltetracarboxylic dianhydride, 2,3,3′,4′-biphenyltetracarboxylic dianhydride, bis(phthalic acid)phenylphosphine oxide dianhydride, p-phenylene-bis(triphenylphthalic)dianhydride, m-phenylene-bis(triphenylphthalic)dianhydride, bis(triphenylphthalic acid)-4,4′-diphenyl ether dianhydride, bis(triphenylphthalic acid)-4,4′-diphenylmethane dianhydride, butanetetracarboxylic dianhydride, 1,2,3,4-cyclobutanetetracarboxylic dianhydride, 1,3-dimethyl-1,2,3,4-cyclobutanetetracarboxylic acid, 1,2,3,4-cyclopentanetetracarboxylic dianhydride, 2,3,5-tricarboxycyclopentylacetic dianhydride, 3,5,6-tricarboxynorbornane-2-acetic dianhydride, 2,3,4,5-tetrahydrofurantetracarboxylic dianhydride, 5-(2,5-dioxotetrahydrofuran))-3-methyl-3-cyclohexene-1,2-dicarboxylic dianhydride, and bicyclo[2,2,2]-oct-7-ene-2,3,5,6-tetracarboxylic dianhydride; and aliphatic tetracarboxylic dianhydrides having an aromatic ring, such as 1,3,3a,4,5,9b-hexahydro-2,5-dioxo-3-furanyl)-naphtho[1,2-c]furan-1,3-dione, 1,3,3a,4,5,9b-hexahydro-5-methyl-5-(tetrahydro-2,5-dioxo-3-furanyl)-naphtho[1,2-c]furan-1,3-dione, 1,3,3a,4,5,9b-hexahydro-8-methyl-5-(tetrahydro-2,5-dioxo-3-furanyl)-naphtho[1,2-c]furan-1,3-dione, or any combination thereof.

In some examples, the diamine benzoxazole comprises benzo[d]oxazole-2,5-diamine, benzo[d]oxazole-2,6-diamine, 2-(4-aminophenyl)benzo[d]oxazol-5-amine, 2-(4-aminophenyl)benzo[d]oxazol-6-amine, or a combination thereof.

In some examples, the diamine benzimidazole comprises 1H-benzo[d]imidazole-2,5-diamine, 1H-benzo[d]imidazole-2,6-diamine, 2-(4-aminophenyl)-1H-benzo[d]imidazol-5-amine, 2-(4-aminophenyl)-1H-benzo[d]imidazol-6-amine, or a combination thereof.

In some examples, a molar ratio of the repeating units derived from the diamine benzoxazole to the repeating units derived from the diamine benzimidazole is from about 30:70 to about 70:30.

In some examples, a molar ratio of the repeating units derived from the diamine benzoxazole to the repeating units derived from the diamine benzimidazole is from about 30:70 to about 50:50.

In some examples, a molar ratio of the repeating units derived from the diamine benzoxazole to the repeating units derived from the diamine benzimidazole is from about 35:65 to about 45:55.

In some examples, the adhesion promoting layer has a thickness from about 2 μm to about 25 μm.

Another example embodiment of the present disclosure is directed to a method of fabricating a semiconductor device package. The method comprises providing a polyimide precursor on a surface, curing the polyimide precursor to obtain a polyimide layer, and providing an electrically insulative material over the polyimide layer. The polyimide layer contains repeating units derived from a tetracarboxylic dianhydride and at least one diamine containing a functional group.

In some examples, the electrically insulative material comprises an epoxy resin.

In some examples, the method further comprises curing the electrically insulative material.

In some examples, the functional group is an azole.

In some examples, the azole is an oxazole or an imidazole.

In some examples, the at least one diamine comprises a diamine benzoxazole and/or a diamine benzimidazole.

In some examples, the at least one diamine comprises a diamine benzoxazole and a diamine benzimidazole.

In some examples, the polyimide precursor is prepared by mixing a first portion of the tetracarboxylic dianhydride, the diamine benzoxazole, and a polar organic solvent in a first vessel to form a first polyamic acid, mixing a second portion of the tetracarboxylic dianhydride, the diamine benzimidazole, and a polar organic solvent in a second vessel to form a second polyamic acid, combining the first polyamic acid with the second polyamic acid to form a polyamic acid mixture, and heating the polyamic acid mixture to a temperature of about 50° C. to about 100° C. to form the polyimide precursor.

In some examples, the polar organic solvent comprises N,N-dimethylacetamide, N-methyl-2-pyrrolidone, and/or dimethylformamide.

In some examples, a molar ratio of the first portion of the tetracarboxylic dianhydride to the diamine benzoxazole is from about 0.9 to about 1.1.

In some examples, a molar ratio of the second portion of the tetracarboxylic dianhydride to the diamine benzimidazole is from about 0.9 to about 1.1.

In some examples, a molar ratio of the diamine benzoxazole to the diamine benzimidazole is from about 30:70 to about 70:30.

In some examples, a molar ratio of the diamine benzoxazole to the diamine benzimidazole is from about 30:70 to about 50:50.

In some examples, a molar ratio of the diamine benzoxazole to the diamine benzimidazole is from about 35:65 to about 45:55.

In some examples, the method further comprises adding a crosslinking agent to the polyamic acid mixture.

In some examples, the crosslinking agent comprises hexamethylenediamine, p-xylylenediamine, ethylenediamine, polyethyleneimine, diethyltriamine, and/or dimethylethyldiamine.

In some examples, the molar ratio of the crosslinking agent to the polyimide precursor is from about 0.1 to about 0.3.

In some examples, providing the polyimide precursor comprises spin coating, spray coating, or dip coating.

In some examples, curing the polyimide precursor comprises heating the precursor to a temperature of from about 150° C. to about 350° C. for a time period from about 1 hour to about 2 hours.

In some examples, the method further comprises degassing the polyimide precursor after providing the polyimide precursor and before curing, wherein degassing comprises heating the precursor to a temperature of from about 50° C. to about 100° C. for a time period from about 30 min to about 60 min.

In some examples, the polyimide precursor is prepared by mixing the tetracarboxylic dianhydride, the diamine benzoxazole, the diamine benzimidazole, and a polar organic solvent in a vessel to form a polyamic acid, and heating the polyamic acid to a temperature of about 50° C. to about 100° C. to form the polyimide precursor.

In some examples, the polar organic solvent comprises N,N-dimethylacetamide, N-methyl-2-pyrrolidone, and/or dimethylformamide.

In some examples, a molar ratio of the tetracarboxylic dianhydride to the total of the diamine benzoxazole and the diamine benzimidazole is from about 0.9 to about 1.1.

In some examples, a molar ratio of the diamine benzoxazole to the diamine benzimidazole is from about 30:70 to about 70:30.

In some examples, a molar ratio of the diamine benzoxazole to the diamine benzimidazole is from about 30:70 to about 50:50.

In some examples, a molar ratio of the diamine benzoxazole to the diamine benzimidazole is from about 35:65 to about 45:55.

In some examples, the method further comprises adding a crosslinking agent to the polyamic acid mixture.

In some examples, the crosslinking agent comprises hexamethylenediamine, p-xylylenediamine, ethylenediamine, polyethyleneimine, diethyltriamine, and/or dimethylethyldiamine.

In some examples, the molar ratio of the crosslinking agent to the polyimide precursor is from about 0.1 to about 0.3.

In some examples, the tetracarboxylic dianhydride is represented by the following formula (TD11) or (TD12):

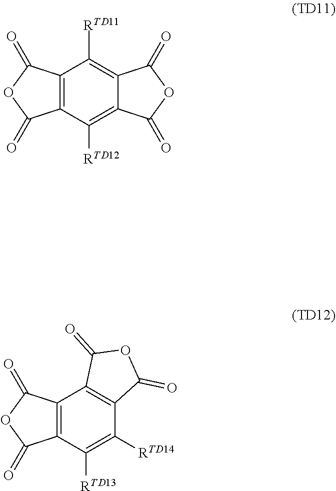

wherein R^{TD11}, R^{TD12}, R^{TD13}, and R^{TD14} each independently represent a hydrogen atom, a carboxyl group, a substituted or unsubstituted alkyl group, or a substituted or unsubstituted phenyl group.

In some examples, the tetracarboxylic dianhydride comprises pyromellitic dianhydride, methylpyromellitic dianhydride, dimethylpyromellitic dianhydride, ethylpyromellitic dianhydride, diethylpyromellitic dianhydride, phenylpyromellitic dianhydride, diphenylpyromellitic dianhydride, 1,2,3,4,5-benzenepentacarboxylic 1,2,4,5-dianhydride, 1,2,3,4,5-benzenepentacarboxylic 1,2,3,4-dianhydride, benzenehexacarboxylic 1,2,4,5-dianhydride, and benzenehexacarboxylic 1,2,3,4-dianhydride, or a combination thereof.

In some examples, the tetracarboxylic dianhydride is represented by the following formula (TD21) or (TD22):

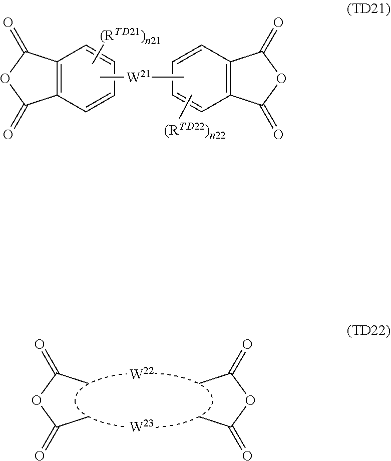

wherein R^{TD21} and R^{TD22} each independently represent a hydrogen atom, a carboxyl group, a substituted or unsubstituted alkyl group, or a substituted or unsubstituted phenyl group;
n21 and n22 each independently represent 0, or an integer of 1 to 3;
W²¹ represents a single bond, or any one group of the following 1) to 8):
1) —C(═O)—, —C(═O)—O—, —C(═O)NH—, or —O—;
2) an alkylene group (for example, an alkylene group having 1 to 12 carbon atoms);
3) a fluoroalkylene group (for example, an alkylene group having 1 to 12 carbon atoms, having at least one hydrogen atom substituted with a fluorine atom);
4) —Si(—R^{TD23})(—R^{TD24})— (in which R^{TD23} and R^{TD24} each independently represent an alkyl group (for example, an alkyl group having 1 to 3 carbon atoms), an aryl group (for example, a phenyl group and a naphthyl group), or an alkoxy group);
5) —O—Ph—R^{TD25}—Ph—O— (in which Ph represents a phenylene group, and R^{TD25} represents —S—S—, —S(═O)₂, an ester group, or an amide group);
6) —P(═O)(—R^{TD26})— (in which R^{TD26} represents an aryl group (for example, a phenyl group), an ester group, or an amide group);
7) —C(—Ph^{A})(—Ph^{A})—Ph—R^{TD27}—Ph—C(—Ph^{A})(—Ph^{A})(in which Ph represents a phenylene group, Ph^{A} represents a phenyl group, and R^{TD27}'s each independently represent —O—, an alkyl group (for example, an alkyl group having 1 to 6 carbon atoms), or an aryl group (for example, a phenyl group and a naphthyl group)); and
8) —O—(—R^{TD28})—O— (in which R^{TD28} represents an alkylene group (for example, an alkylene group having 1 to 12 carbon atoms)); and
W²² and W²³ represent atomic groups which are bonded to each other to form a substituted or unsubstituted condensed aromatic ring or a substituted or unsubstituted heterocycle.

In some examples, the tetracarboxylic dianhydride comprises 3,3′,4,4′-benzophenonetetracarboxylic dianhydride, 3,3′,4,4′-biphenylsulfonetetracarboxylic dianhydride, 1,4,5,8-naphthalenetetracarboxylic dianhydride, 2,3,6,7-naphthalenetetracarboxylic dianhydride, 3,3′,4,4′-biphenyl ether tetracarboxylic dianhydride, 3,3′,4,4′-dimethyldiphenylsilanetetracarboxylic dianhydride, 3,3′,4,4′-tetraphenylsilanetetracarboxylic dianhydride, 1,2,3,4-furantetracarboxylic dianhydride, 4,4′-bis(3,4-dicarboxyphenoxy)diphenylsulfide dianhydride, 4,4′-bis(3,4-dicarboxyphenoxy)diphenylsulfone dianhydride, 4,4′-bis(3,4-dicarboxyphenoxy)diphenylpropane dianhydride, 3,3,4,4′-perfluoroisopropylidene diphthalic dianhydride, 3,3′,4,4′-biphenyltetracarboxylic dianhydride, 2,3,3′,4′-biphenyltetracarboxylic dianhydride, bis(phthalic acid)phenylphosphine oxide dianhydride, p-phenylene-bis(triphenylphthalic)dianhydride, m-phenylene-bis(triphenylphthalic)dianhydride, bis(triphenylphthalic acid)-4,4′-diphenyl ether dianhydride, bis(triphenylphthalic acid)-4,4′-diphenylmethane dianhydride, butanetetracarboxylic dianhydride, 1,2,3,4-cyclobutanetetracarboxylic dianhydride, 1,3-dimethyl-1,2,3,4-cyclobutanetetracarboxylic acid, 1,2,3,4-cyclopentanetetracarboxylic dianhydride, 2,3,5-tricarboxycyclopentylacetic dianhydride, 3,5,6-tricarboxynorbornane-2-acetic dianhydride, 2,3,4,5-tetrahydrofurantetracarboxylic dianhydride, 5-(2,5-dioxotetrahydrofuran))-3-methyl-3-cyclohexene-1,2-dicarboxylic dianhydride, and bicyclo[2,2,2]-oct-7-ene-2,3,5,6-tetracarboxylic dianhydride; and aliphatic tetracarboxylic dianhydrides having an aromatic ring, such as 1,3,3a,4,5,9b-hexahydro-2,5-dioxo-3-furanyl)-naphtho[1,2-c]furan-1,3-dione, 1,3,3a,4,5,9b-hexahydro-5-methyl-5-(tetrahydro-2,5-dioxo-3-furanyl)-naphtho[1,2-c]furan-1,3-dione, 1,3,3a,4,5,9b-hexahydro-8-methyl-5-(tetrahydro-2,5-dioxo-3-furanyl)-naphtho[1,2-c]furan-1,3-dione, or any combination thereof.

In some examples, the diamine benzoxazole comprises benzo[d]oxazole-2,5-diamine, benzo[d]oxazole-2,6-diamine, 2-(4-aminophenyl)benzo[d]oxazol-5-amine, 2-(4-aminophenyl)benzo[d]oxazol-6-amine, or a combination thereof.

In some examples, the diamine benzimidazole comprises 1H-benzo[d]imidazole-2,5-diamine, 1H-benzo[d]imidazole-2,6-diamine, 2-(4-aminophenyl)-1H-benzo[d]imidazol-5-amine, 2-(4-aminophenyl)-1H-benzo[d]imidazol-6-amine, or a combination thereof.

In some examples, the adhesion promoting layer has a thickness from about 2 μm to about 25 μm.

In some examples, the surface comprises copper, copper(II) oxide, and/or copper(II) hydroxide.

In some examples, the surface comprises nickel, nickel(II) oxide, and/or nickel(II) hydroxide.

In some examples, the surface comprises aluminum, aluminum oxide, and/or aluminum hydroxide.

In some examples, the surface comprises hydrogenated silicon oxide.

In some examples, the surface comprises silicon nitride.

In some examples, the surface comprises silicon carbide.

In some examples, the surface comprises a Pb—Sn alloy.

In some examples, the surface comprises gold.

In some examples, the surface comprises silver.

In some examples, the surface comprises an organic material.

In some examples, the organic material comprises a polyimide.

In some examples, the semiconductor device package comprises a wide bandgap semiconductor device.

In some examples, the wide bandgap semiconductor device comprises a silicon carbide-based MOSFET, a silicon carbide-based Schottky diode, or a Group III nitride-based high electron mobility transistor.

In some examples, the surface comprises an electrically conductive material.

In some examples, the surface comprises a semiconductor material.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device package, comprising:
a first structure having a first surface in the semiconductor device package;
a second structure having a second surface in the semiconductor device package; and
an adhesion promoting layer in contact with the first surface on a first side and the second surface on a second side, wherein the adhesion promoting layer comprises a polyimide containing repeating units derived from a tetracarboxylic dianhydride and at least one diamine containing a functional group.

2. The semiconductor device package of claim 1, wherein the tetracarboxylic dianhydride is represented by the following formula (TD11) or (TD12): 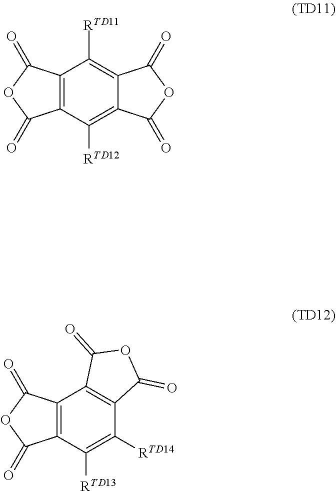
wherein R^{TD11}, R^{TD12}, R^{TD13}, and R^{TD14} each independently represent a hydrogen atom, a carboxyl group, a substituted or unsubstituted alkyl group, or a substituted or unsubstituted phenyl group.

3. The semiconductor device package of claim 2, wherein the tetracarboxylic dianhydride comprises pyromellitic dianhydride, methylpyromellitic dianhydride, dimethylpyromellitic dianhydride, ethylpyromellitic dianhydride, diethylpyromellitic dianhydride, phenylpyromellitic dianhydride, diphenylpyromellitic dianhydride, 1,2,3,4,5-benzenepentacarboxylic 1,2,4,5-dianhydride, 1,2,3,4,5-benzenepentacarboxylic 1,2,3,4-dianhydride, benzenehexacarboxylic 1,2,4,5-dianhydride, and benzenehexacarboxylic 1,2,3,4-dianhydride, or a combination thereof.

4. The semiconductor device package of claim 1, wherein the tetracarboxylic dianhydride is represented by the following formula (TD21) or (TD22): 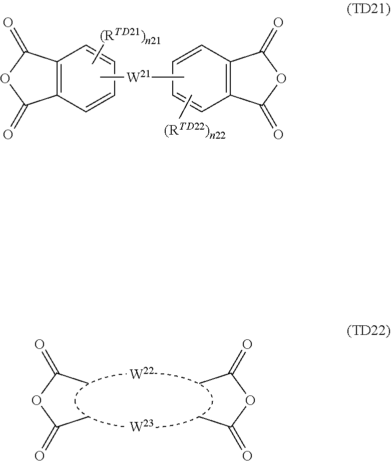
wherein R^{TD21} and R^{TD22} each independently represent a hydrogen atom, a carboxyl group, a substituted or unsubstituted alkyl group, or a substituted or unsubstituted phenyl group;
n21 and n22 each independently represent 0, or an integer of 1 to 3;
W²¹ represents a single bond, or any one group of the following 1) to 8):
1) —C(═O)—, —C(═O)—O—, —C(═O)NH—, or —O—;
2) an alkylene group (for example, an alkylene group having 1 to 12 carbon atoms);
3) a fluoroalkylene group (for example, an alkylene group having 1 to 12 carbon atoms, having at least one hydrogen atom substituted with a fluorine atom);
4) —Si(—R^{TD23})(—R^{TD24})— (in which R^{TD23} and R^{TD24} each independently represent an alkyl group (for example, an alkyl group having 1 to 3 carbon atoms), an aryl group (for example, a phenyl group and a naphthyl group), or an alkoxy group);
5) —O—Ph—R^{TD25}—Ph—O— (in which Ph represents a phenylene group, and R^{TD25} represents —S—S—, —S(═O)₂—, an ester group, or an amide group);
6) —P(═O)(—R^{TD26})— (in which R^{TD26} represents an aryl group (for example, a phenyl group), an ester group, or an amide group);
7) —C(—Ph^{A})(—Ph^{A})—Ph—R^{TD27}—Ph—C(—Ph^{A})(—Ph^{A})(in which Ph represents a phenylene group, Ph^{A} represents a phenyl group, and R^{TD27}'s each independently represent —O—, an alkyl group (for example, an alkyl group having 1 to 6 carbon atoms), or an aryl group (for example, a phenyl group and a naphthyl group)); and
8) —O—(—R^{TD28})—O— (in which R^{TD28} represents an alkylene group (for example, an alkylene group having 1 to 12 carbon atoms)); and
W²² and W²³ represent atomic groups which are bonded to each other to form a substituted or unsubstituted condensed aromatic ring or a substituted or unsubstituted heterocycle.

5. The semiconductor device package of claim 4, wherein the tetracarboxylic dianhydride comprises 3,3′,4,4′-benzophenonetetracarboxylic dianhydride, 3,3′,4,4′-biphenylsulfonetetracarboxylic dianhydride, 1,4,5,8-naphthalenetetracarboxylic dianhydride, 2,3,6,7-naphthalenetetracarboxylic dianhydride, 3,3′,4,4′-biphenyl ether tetracarboxylic dianhydride, 3,3′,4,4′-dimethyldiphenylsilanetetracarboxylic dianhydride, 3,3′,4,4′-tetraphenylsilanetetracarboxylic dianhydride, 1,2,3,4-furantetracarboxylic dianhydride, 4,4′-bis(3,4-dicarboxyphenoxy)diphenylsulfide dianhydride, 4,4′-bis(3,4-dicarboxyphenoxy)diphenylsulfone dianhydride, 4,4′-bis(3,4-dicarboxyphenoxy)diphenylpropane dianhydride, 3,3,4,4′-perfluoroisopropylidene diphthalic dianhydride, 3,3′,4,4′-biphenyltetracarboxylic dianhydride, 2,3,3′,4′-biphenyltetracarboxylic dianhydride, bis(phthalic acid)phenylphosphine oxide dianhydride, p-phenylene-bis(triphenylphthalic)dianhydride, m-phenylene-bis(triphenylphthalic)dianhydride, bis(triphenylphthalic acid)-4,4′-diphenyl ether dianhydride, bis(triphenylphthalic acid)-4,4′-diphenylmethane dianhydride, butanetetracarboxylic dianhydride, 1,2,3,4-cyclobutanetetracarboxylic dianhydride, 1,3-dimethyl-1,2,3,4-cyclobutanetetracarboxylic acid, 1,2,3,4-cyclopentanetetracarboxylic dianhydride, 2,3,5-tricarboxycyclopentylacetic dianhydride, 3,5,6-tricarboxynorbornane-2-acetic dianhydride, 2,3,4,5-tetrahydrofurantetracarboxylic dianhydride, 5-(2,5-dioxotetrahydrofuran))-3-methyl-3-cyclohexene-1,2-dicarboxylic dianhydride, and bicyclo[2,2,2]-oct-7-ene-2,3,5,6-tetracarboxylic dianhydride; and aliphatic tetracarboxylic dianhydrides having an aromatic ring, such as 1,3,3a,4,5,9b-hexahydro-2,5-dioxo-3-furanyl)-naphtho[1,2-c]furan-1,3-dione, 1,3,3a,4,5,9b-hexahydro-5-methyl-5-(tetrahydro-2,5-dioxo-3-furanyl)-naphtho[1,2-c]furan-1,3-dione, 1,3,3a,4,5,9b-hexahydro-8-methyl-5-(tetrahydro-2,5-dioxo-3-furanyl)-naphtho[1,2-c]furan-1,3-dione, or any combination thereof.

6. The semiconductor device package of claim 1, wherein the functional group is an azole.

7. The semiconductor device package of claim 6, wherein the azole is an oxazole or an imidazole.

8. The semiconductor device package of claim 1, wherein the at least one diamine comprises a diamine benzoxazole and/or a diamine benzimidazole.

9. The semiconductor device package of claim 1, wherein the at least one diamine comprises a diamine benzoxazole and a diamine benzimidazole.

10. The semiconductor device package of claim 8, wherein the diamine benzoxazole comprises benzo[d]oxazole-2,5-diamine, benzo[d]oxazole-2,6-diamine, 2-(4-aminophenyl)benzo[d]oxazol-5-amine, 2-(4-aminophenyl)benzo[d]oxazol-6-amine, or a combination thereof.

11. The semiconductor device package of claim 8, wherein the diamine benzimidazole comprises 1H-benzo[d]imidazole-2,5-diamine, 1H-benzo[d]imidazole-2,6-diamine, 2-(4-aminophenyl)-1H-benzo[d]imidazol-5-amine, 2-(4-aminophenyl)-1H-benzo[d]imidazol-6-amine, or a combination thereof.

12. The semiconductor device package of claim 9, wherein a molar ratio of the repeating units derived from the diamine benzoxazole to the repeating units derived from the diamine benzimidazole is from about 30:70 to about 70:30.

13. The semiconductor device package of claim 9, wherein a molar ratio of the repeating units derived from the diamine benzoxazole to the repeating units derived from the diamine benzimidazole is from about 30:70 to about 50:50.

14. The semiconductor device package of claim 9, wherein a molar ratio of the repeating units derived from the diamine benzoxazole to the repeating units derived from the diamine benzimidazole is from about 35:65 to about 45:55.

15. The semiconductor device package of claim 1, wherein the adhesion promoting layer has a thickness from about 2 μm to about 25 μm.

16. The semiconductor device package of claim 1, wherein the first structure comprises an electrically insulative material.

17. The semiconductor device package of claim 1, wherein the first surface comprises an epoxy resin.

18. The semiconductor device package of claim 1, wherein the second structure comprises an electrically conductive material, a semiconductor structure, copper, copper(II) oxide, copper(II) hydroxide, nickel, nickel(II) oxide, nickel(II) hydroxide, aluminum, aluminum oxide, aluminum hydroxide, hydrogenated silicon oxide, silicon nitride, silicon carbide, a Pb—Sn alloy, gold, silver, an organic material, a polyimide.

19.-30. (canceled)

31. The semiconductor device package of claim 1, wherein the semiconductor device package comprises a wide bandgap semiconductor device.

32. The semiconductor device package of claim 31, wherein the wide bandgap semiconductor device comprises a silicon carbide-based MOSFET, a silicon carbide-based Schottky diode, or a Group III nitride-based high electron mobility transistor.

33. A semiconductor device package, comprising:
a semiconductor die comprising a wide bandgap semiconductor device;
a submount;
a die-attach material coupling the semiconductor die to the submount;
an encapsulating material; and
an adhesion promoting layer comprising a polyimide containing repeating units derived from a tetracarboxylic dianhydride, a diamine benzoxazole, and a diamine benzimidazole.

34.-59. (canceled)

60. A method of fabricating a semiconductor device package, comprising:
providing a polyimide precursor on a surface;
curing the polyimide precursor to obtain a polyimide layer; and
providing an electrically insulative material over the polyimide layer;
wherein the polyimide layer contains repeating units derived from a tetracarboxylic dianhydride and at least one diamine containing a functional group.

61.-110. (canceled)
